(19) United States
(12) Patent Application Publication
(10) Pub. No.: US 2006/0175620 A1
(43) Pub. Date: Aug. 10, 2006

(54) Epitaxial wafer for light emitting diode

(75) Inventor: Yosuke Komori, Hitachi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Hitachi Cable, Ltd., Tokyo (JP)

(21) Appl. No.: 11/269,563

(22) Filed: Nov. 9, 2005

(30) Foreign Application Priority Data
Feb. 7, 2005 (JP) 2005-030919

(51) Int. Cl. H01L 33/00

(52) U.S. Cl. 257/86; 257/E33.024

(57) ABSTRACT

An epitaxial wafer for LED is provided with a layered structure by sequentially growing a p-type AlGaAs active layer 2, and a n-type AlGaAs window layer 1 on a p-type GaAs substrate 3 by liquid phase epitaxy (LPE) growth using Boat method. A maximum value of a dislocation density in a plane of the p-type type GaAs substrate is set within a range from 5,000 to 22,000 pcs/cm². The epitaxial wafer for LED with low cost, excellent crystalline quality and high device quality can be obtained.

The present application is based on Japanese Patent Application No. 2005-030919 filed on Feb. 7, 2005, the entire contents of which are incorporated herein by reference.

### BACKGROUND OF THE INVENTION

1. Field of the Invention

The present invention relates to an epitaxial wafer for light emitting diode, and particularly to an epitaxial wafer for light emitting diode using hetero junction with low cost, excellent crystalline quality and high device quality.

2. Description of the Related Art

In recent years, the light emitting diode (LED) used as a light emitting element has been improved in luminance, and has been put to practical use in many manners as a material for a light source of devices having a clear displaying function with an excellent visibility such as information panel, railroad crossing signal, etc.

So-called “low cost and multipurpose” LED is fabricated as follows. As a main component for a pn-junction in the light-emitting element, GaP or AlGaAs is used. As a fabrication method, the liquid phase epitaxy (LPE) using the lateral Boat method (slide Boat method) is used. Regarding the structure, the LED having a hetero structure such as single hetero structure (SH structure), double hetero structure (DH structure), back-reflect type DH structure has been developed (DDH structure).

An epitaxial wafer having the single hetero (SH) structure, which is one of the simplest hetero structures, will be explained. The epitaxial wafer having the single hetero (SH) structure is fabricated by sequentially growing a p-type AlGaAs cladding layer and a n-type AlGaAs window layer on a p-type GaAs substrate by using the liquid phase epitaxy (LPE) method.

Further, an epitaxial wafer having the double hetero (DH) structure will be explained. The epitaxial wafer having the double hetero (DH) structure is fabricated by sequentially growing a p-type AlGaAs cladding layer, a p-type AlGaAs active layer, and a n-type AlGaAs window layer on a p-type GaAs substrate by using the liquid phase epitaxy (LPE) method.

Such methods of fabricating the epitaxial wafer for LED using the liquid phase epitaxy (LPE) method are disclosed in Japanese Patent Application Laid-Open publications. For example, Japanese Patent Application Laid-Open (Kokai) No. 7-30150 discloses a method of fabricating an epitaxial wafer for LED using a p-type GaAs substrate. Japanese Patent Application Laid-Open (Kokai) Nos. 8-46238 and 5-21848 respectively disclose a method of fabricating an epitaxial wafer for LED using an n-type GaAs substrate.

However, the prior arts do not clearly disclose or define an appropriate numerical range of a dislocation density (etch pit density, called as “EPD”) of a p-type substrate or n-type substrate used for the liquid phase epitaxy (LPE) method in the epitaxial wafer for LED.

In the epitaxial growth using the liquid phase epitaxy (LPE) method, the dislocation density in a plane of an employed substrate relates to a crystalline quality of the epitaxial layer per se. When a specification (requirement) concerning the dislocation density in the plane of the employed substrate is strictly determined, the cost of fabricating the epitaxial wafer becomes higher. On the contrary, when the specification (requirement) concerning the dislocation density in the plane of the employed substrate is loosely determined, the crystalline quality of the epitaxial layer per se will be degraded, so that a reliability of the LED using such an epitaxial layer will be deteriorated.

### SUMMARY OF THE INVENTION

Accordingly, it is an object of the present invention to provide a high quality epitaxial wafer with low cost, excellent crystalline quality, and high device quality, by setting a maximum value of a dislocation density in a plane of a substrate employed in the liquid phase epitaxy method within an appropriate range.

According to a first feature of the present invention, an epitaxial wafer for light emitting diode comprises:

a first conductivity type GaAs substrate; and

a layered structure including a first conductivity type AlGaAs active layer and a second conductivity type AlGaAs window layer sequentially grown on the first conductivity type GaAs substrate by liquid phase epitaxy (LPE) growth using Boat method;

wherein a maximum value of a dislocation density in a plane of the first conductivity type GaAs substrate is within a range from 5,000 to 22,000 pcs/cm².

According to a second feature of the present invention, an epitaxial wafer for light emitting diode comprises:

a first conductivity type GaAs substrate; and

a layered structure including a first conductivity type AlGaAs cladding layer, a first conductivity type AlGaAs active layer and a second conductivity type AlGaAs window layer sequentially grown on the first conductivity type GaAs substrate by liquid phase epitaxy (LPE) growth using Boat method;

wherein a maximum value of a dislocation density in a plane of the first conductivity type GaAs substrate is within a range from 5,000 to 22,000 pcs/cm².

According to a third feature of the present invention, an epitaxial wafer for light emitting diode comprises:

a first conductivity type GaAs substrate; and

a layered structure including a first conductivity type AlGaAs cladding layer, a first conductivity type AlGaAs active layer and a second conductivity type AlGaAs window layer sequentially grown on the first conductivity type GaAs substrate by liquid phase epitaxy (LPE) growth using Boat method, and the first conductivity type GaAs substrate being removed by selective etching;

wherein a maximum value of a dislocation density in a plane of the first conductivity type GaAs substrate is within a range from 5,000 to 22,000 pcs/cm².

According to a fourth feature of the invention, the first conductivity type may be p-type and the second conductivity type may be n-type.

According to a fifth feature of the invention, the first conductivity type may be n-type and the second conductivity type may be p-type.

According to a sixth feature of the present invention, an epitaxial wafer for light emitting diode comprises:

a first conductivity type GaAs substrate; and

a layered structure including a first conductivity type AlGaAs active layer and a second conductivity type AlGaAs window layer sequentially grown on the first conductivity type GaAs substrate;

wherein a maximum value of a dislocation density in a plane of the first conductivity type GaAs substrate is within a range from 5,000 to 22,000 pcs/cm².

According to a seventh feature of the present invention, an epitaxial wafer for light emitting diode comprises:

a first conductivity type GaAs substrate; and

a layered structure including a first conductivity type AlGaAs cladding layer, a first conductivity type AlGaAs active layer and a second conductivity type AlGaAs window layer sequentially grown on the first conductivity type GaAs substrate;

wherein a maximum value of a dislocation density in a plane of the first conductivity type GaAs substrate is within a range from 5,000 to 22,000 pcs/cm².

According to an eighth feature of the present invention, an epitaxial wafer for light emitting diode comprises:

a first conductivity type GaAs substrate; and

a layered structure including a first conductivity type AlGaAs cladding layer, a first conductivity type AlGaAs active layer and a second conductivity type AlGaAs window layer sequentially grown on the first conductivity type GaAs substrate, and the first conductivity type GaAs substrate being removed by selective etching;

wherein a maximum value of a dislocation density in a plane of the first conductivity type GaAs substrate is within a range from 5,000 to 22,000 pcs/cm².

According to a ninth feature of the present invention, a method of fabricating an epitaxial wafer for light emitting diode comprises the steps of:

determining a luminance fall rate of the light emitting diode depending on a continuous operation time;

selecting a GaAs substrate having a dislocation density which meets the luminance fall rate determined in the determining step; and

forming a layered structure including an AlGaAs active layer and an AlGaAs window layer sequentially grown on the selected GaAs substrate.

According to a tenth feature of the present invention, a method of fabricating an epitaxial wafer for light emitting diode comprises the steps of:

determining a luminance fall rate of the light emitting diode depending on a continuous operation time;

selecting a GaAs substrate having a dislocation density which meets the luminance fall rate determined in the determining step; and

forming a layered structure including an AlGaAs cladding layer, an AlGaAs active layer and an AlGaAs window layer sequentially grown on the selected GaAs substrate.

According to an eleventh feature of the present invention, a method of fabricating an epitaxial wafer for light emitting diode comprises the steps of:

determining a luminance fall rate of the light emitting diode depending on a continuous operation time;

selecting a GaAs substrate having a dislocation density which meets the luminance fall rate determined in the determining step; and

forming a layered structure including an AlGaAs cladding layer, an AlGaAs active layer and an AlGaAs window layer sequentially grown on the selected GaAs substrate; and

removing the GaAs substrate by selective etching.

According to a twelfth feature of the present invention, the selecting step may select a GaAs substrate having a dislocation density ranging from 5,000 to 22,000 pcs/cm².

Firstly, the present invention relates to an epitaxial wafer for LED having a layered structure (any one of single hetero (SH) structure, double hetero (DH) structure, and double hetero structure in which the substrate is removed, so-called DDH structure) formed by the liquid phase epitaxy (LPE) growth using the Boat method. The reason why the liquid phase epitaxy (LPE) growth is employed in the present invention is as follows. The liquid phase epitaxy (LPE) growth is less affected than other vapor phase growth methods, by the dislocation density (EPD) of the substrate plane.

Secondly, the present invention is based on the fact found by the Inventors concerning the substrate employed in the liquid phase epitaxy (LPE) growth.

If a specification (requirement) concerning a dislocation density of a substrate plane is strictly determined, e.g. the maximum value of the dislocation density in a plane of a p-type substrate to be employed in the liquid phase epitaxy (LPE) growth is determined as 1,000 pcs/cm², defects of the liquid phase epitaxial layer per se will not occur. However, supposing that a substrate grown by the Boat method is employed, a yield of the substrate may become extremely low. Otherwise, even if a substrate grown by vertical gradient freeze (VGF) method or vertical Bridgman (VB) method is employed, a unit cost of the substrate may become extremely high in any case. Therefore, a liquid phase epitaxy substrate for LED (epitaxial wafer for LED) with low cost cannot be provided.

On the other hand, if the specification (requirement) concerning the dislocation density is determined too loosely, e.g. the maximum value of the dislocation density in the plane of the p-type substrate to be employed in the liquid phase epitaxy (LPE) growth is determined as 30,000 pcs/cm², defects will occur when the liquid phase epitaxy (LPE) is grown in a portion where the dislocation density is 30,000 pcs/cm². As a result of deterioration of reliability in forming the LED chip, the final product will not satisfy the specification (requirement) for the desired LED.

Accordingly, in the present invention, a high quality epitaxial wafer with low cost, excellent crystalline quality, and high device quality is provided, by setting the maximum value of the dislocation density in the plane of the substrate employed in the liquid phase epitaxy (LPE) growth within a range from 5,000 to 22,000 pcs/cm².

In the present invention, the reason why a lower limit of the maximum value of the dislocation density in the substrate plane is determined as 5,000 pcs/cm² will be explained as follows. Since the substrate grown by the Boat method has a higher dislocation density than the substrate grown by the VB method or VGF method, if the maximum value of the dislocation density in the substrate plane is less than 5,000 pcs/cm², almost all the substrates will not comply with a reliability requirement. On the other hand, the reason why an upper limit of the maximum value of the dislocation density in the substrate plane is determined as 22,000 pcs/cm² will be explained as follows. If the maximum value of the dislocation density in the substrate plane is greater than 22,000 pcs/cm², a relative output of the LED will be lower than 90% and the final product will not satisfy the reliability requirement.

According to the present invention, a high quality epitaxial wafer with low cost and excellent crystalline quality can be provided, by setting the maximum value of the dislocation density in the substrate plane of the epitaxial wafer for LED to be employed in the liquid phase epitaxy (LPE) growth within a range from 5,000 to 22,000 pcs/cm².

By setting the maximum value of the dislocation density in the substrate plane within the range from 5,000 to 22,000 pcs/cm², the crystalline quality of the epitaxy can be kept without being affected by the dislocation density in the substrate plane, so that the LED chip with a high reliability can be provided. However, the maximum value of the dislocation density in the substrate plane is set beyond this range, the dislocation density in the substrate plane will affect on the crystalline quality of the epitaxial layer, thereby deteriorating the reliability of the LED chip. As a result, the fabricated LED chip will not satisfy the specification (reliability requirement). Herein, the LED chip satisfying a condition that the luminance fall rate is 90% or more is admitted as a LED chip that meets the specification (reliability requirement).

### BRIEF DESCRIPTION OF THE DRAWINGS

The present invention will be explained in more detail in conjunction with appended drawings, wherein:

FIG. 1 is a cross sectional view showing an epitaxial wafer for light emitting diode in a first embodiment according to the invention;

FIG. 2 is a graph showing a relationship between EPD values of employed substrate and results of a reliability test of LED chip;

FIG. 3 is a cross sectional view showing an epitaxial wafer for light emitting diode in a second embodiment according to the invention;

FIG. 4 is a cross sectional view showing an epitaxial wafer for light emitting diode in a third embodiment according to the invention; and

FIG. 5 is a cross sectional view of an epitaxial wafer for light emitting diode showing an example of variation according to the invention.

### DESCRIPTION OF THE PREFERRED EMBODIMENTS

Preferred embodiments according to the present invention will be explained in detail hereinafter by referring to the appended drawings.

### 1. First Embodiment

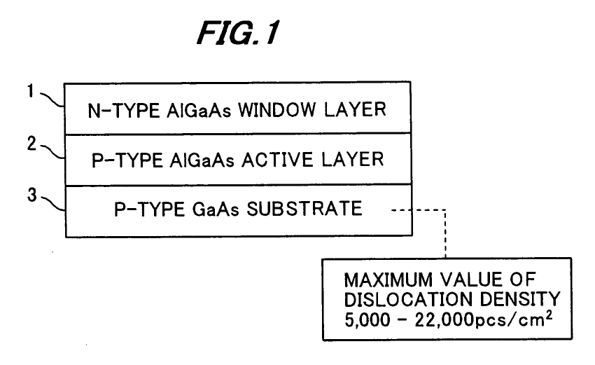

FIG. 1 is a cross sectional view showing an epitaxial wafer for LED having a single hetero (SH) structure in a first embodiment according to the invention. The epitaxial wafer according to the first embodiment comprises a layered structure prepared by sequentially growing a p-type AlGaAs active layer 2 having an Al mixed crystal ratio required for a desired light emission wavelength, and a n-type AlGaAs window layer 1 on a p-type GaAs substrate 3 by liquid phase epitaxy (LPE) method.

At first, the epitaxial wafer for LED having the SH structure shown in FIG. 1 is grown by the liquid phase epitaxy (LPE) method as described above. Then a LED device is fabricated by using this epitaxial wafer. For the purpose of evaluating the reliability of the LED chip, e.g. electric current of 45 mA may be flown to the fabricated LED device for 1,000 hours (reliability test).

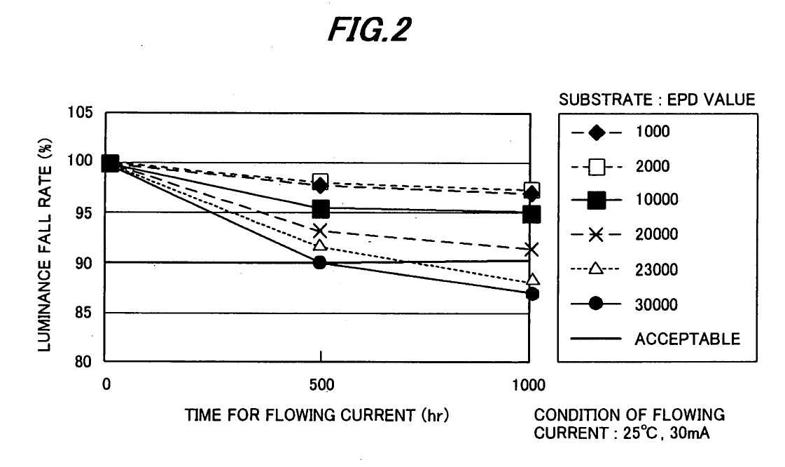

FIG. 2 is a graph showing relationship between maximum values (hereinafter, called as “EPD value”) of the dislocation density (EPD) in the plane of the p-type GaAs substrate employed in the liquid phase epitaxy (LPE) growth and results of the reliability test of the LED chip using the p-type GaAs substrate.

In FIG. 2, a test time (hr) for having flown current is indicated by a horizontal axis and a luminance fall rate (relative output) (%) is indicated by a vertical axis. In the reliability test for the first embodiment, electric current of 30 mA is flown to the LED chip at a temperature of 25° C. for 1,000 hours. In addition, the EPD value in the substrate plane was varied as a parameter for 1,000 pcs/cm², 2,000 pcs/cm², 10,000 pcs/cm², 20,000 pcs/cm², 23,000 pcs/cm², and 30,000 pcs/cm². A horizontal line indicating the luminance fall rate of 90% is a criterion for determining acceptability in the reliability requirement of the LED device. The LED chip satisfying a condition that the luminance fall rate is 90% or more is admitted as a LED chip that meets the reliability requirement.

As clearly understood from the results shown in FIG. 2, in case where the EPD value of the p-type GaAs substrate is 30,000 pcs/cm² and 23,000 pcs/cm², the luminance fall rate for each case is lower than the criterion (90%) of the acceptability, so that the LED chip using such a p-type GaAs substrate does not meet the reliability requirement. On the other hand, the EPD value of the p-type GaAs substrate is 2,000 pcs/cm², 10,000 pcs/cm², and 20,000 pcs/cm², the luminance fall rate for each case is greater than the criterion (90%) of the acceptability, so that the LED chip using such a p-type GaAs substrate meets the reliability requirement. However, unit cost of the p-type GaAs substrate having the EPD values of 2,000 pcs/cm² or 10,000 pcs/cm² becomes extremely high. Therefore, a liquid phase epitaxy substrate for LED (epitaxial wafer for LED) with low cost cannot be provided. In addition, a substrate employed in the liquid phase epitaxy growth is grown by the Boat method. The substrate grown by the Boat method has a higher dislocation density than the substrate grown by the other vapor phase epitaxy methods. Therefore, if the maximum value of the dislocation density in the substrate plane (EPD value) is set less than 5,000 pcs/cm², almost all the substrates grown by the Boat method will not satisfy the acceptability of the reliability requirement. Therefore, it is required that the maximum value of the dislocation density in the substrate plane (EPD value) is 5,000 pcs/cm² or more.

Accordingly, the range from 5,000 pcs/cm² to 22,000 pcs/cm² is admitted as an appropriate range of the maximum value of the dislocation density in the substrate plane (EPD value) for p-type GaAs substrate employed in the liquid phase epitaxy (LPE) growth.

In other words, by using a p-type substrate having the maximum value of the dislocation density in the substrate plane (EPD value) within a range from 5,000 pcs/cm² to 22,000 pcs/cm² as a p-type GaAs substrate 3 for growing the epitaxial wafer for LED having the SH structure shown in FIG. 1, an epitaxial wafer for LED with low cost and high quality can be obtained.

### 2. Second Embodiment

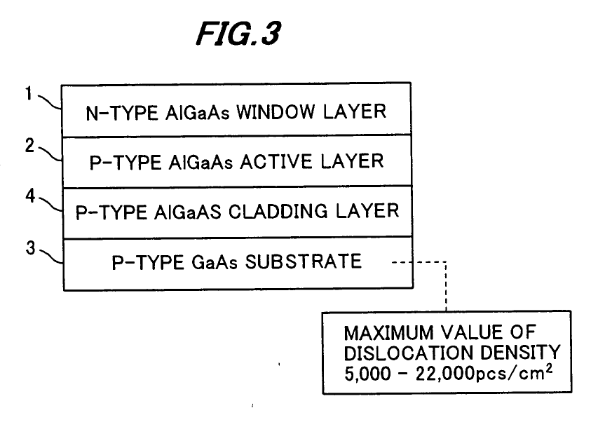

FIG. 3 is a cross sectional view showing an epitaxial wafer for LED having a double hetero (DH) structure in a second embodiment according to the invention. The epitaxial wafer for LED according to the second embodiment comprises a layered structure prepared by sequentially growing a p-type AlGaAs cladding layer 4, a p-type AlGaAs active layer 2 having an Al mixed crystal ratio required for a desired light emission wavelength, and a n-type AlGaAs window layer 1 on a p-type GaAs substrate 3 by the liquid phase epitaxial growth using the Boat method.

By using a p-type substrate having the maximum value of the dislocation density in the substrate plane (EPD value) within a range from 5,000 pcs/cm² to 22,000 pcs/cm² as a p-type GaAs substrate 3 for growing the epitaxial wafer for LED having the DH structure shown in FIG. 3, an epitaxial wafer for LED with low cost, excellent crystalline quality and high device quality can be obtained.

### 3. Third Embodiment

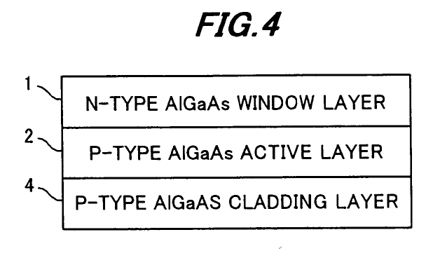

FIG. 4 is a cross sectional view showing an epitaxial wafer for LED having a double hetero structure in which the substrate is removed (DDH structure) in a third embodiment according to the invention. The epitaxial wafer for LED according to the third embodiment comprises a layered structure prepared by sequentially growing a p-type AlGaAs cladding layer 4, a p-type AlGaAs active layer 2 having an Al mixed crystal ratio required for a desired light emission wavelength, and a n-type AlGaAs window layer 1 on a p-type GaAs substrate 3 (not shown in FIG. 4) similarly to the epitaxial wafer shown in FIG. 3 by the liquid phase epitaxial (LPE) growth using the Boat method, and removing the p-type GaAs substrate 3 by using a selective etching after the liquid phase epitaxial (LPE) growth.

By using a p-type substrate having the maximum value of the dislocation density in the substrate plane (EPD value) within a range from 5,000 pcs/cm² to 22,000 pcs/cm² as a p-type GaAs substrate 3 to be removed by the selective etching (cf. FIG. 3) for growing the epitaxial wafer for LED having the DDH structure shown in FIG. 4, an epitaxial wafer for LED with low cost, excellent crystalline quality and high device quality can be obtained.

In each of the first to third embodiments according to the present invention shown in FIGS. 1, 3 and 4, an n-side up layered structure formed on the p-type substrate by the liquid phase epitaxial (LPE) growth is explained. However, these embodiments may be applicable to a LED having p-side up layered structure formed on a n-type GaAs substrate, i.e. the LED having a structure in which a conductivity type of respective n- and p-type layers is opposite to that of the layered structure in the first to third embodiments.

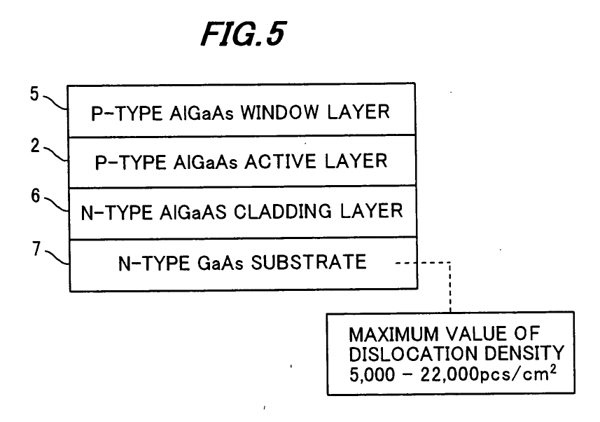

FIG. 5 is a cross sectional view showing an example of variation for a LED epitaxial wafer comprising a layered structure (DH structure) prepared by sequentially growing a n-type AlGaAs cladding layer 6, a p-type AlGaAs active layer 2, and p-type AlGaAs window layer 5 on a n-type GaAs substrate 7 by the liquid phase epitaxial (LPE) growth using the Boat method.

By using a n-type substrate having the maximum value of the dislocation density in the substrate plane (EPD value) within a range from 5,000 pcs/cm² to 22,000 pcs/cm² as a n-type GaAs substrate 7 for growing the epitaxial wafer for LED having the DH structure shown in FIG. 5, an epitaxial wafer for LED with low cost, excellent crystalline quality and high device quality can be obtained.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching herein set forth.

What is claimed is:

1. An epitaxial wafer for light emitting diode, comprising:
a first conductivity type GaAs substrate; and
a layered structure including a first conductivity type AlGaAs active layer and a second conductivity type AlGaAs window layer sequentially grown on the first conductivity type GaAs substrate by liquid phase epitaxy (LPE) growth using Boat method;
wherein a maximum value of a dislocation density in a plane of the first conductivity type GaAs substrate is within a range from 5,000 to 22,000 pcs/cm².

2. The epitaxial wafer for light emitting diode, according to claim 1, wherein:
the first conductivity type is p-type and the second conductivity type is n-type.

3. The epitaxial wafer for light emitting diode, according to claim 1, wherein:
the first conductivity type is n-type and the second conductivity type is p-type.

4. An epitaxial wafer for light emitting diode, comprising:
a first conductivity type GaAs substrate; and
a layered structure including a first conductivity type AlGaAs cladding layer, a first conductivity type AlGaAs active layer and a second conductivity type AlGaAs window layer sequentially grown on the first conductivity type GaAs substrate by liquid phase epitaxy (LPE) growth using Boat method;
wherein a maximum value of a dislocation density in a plane of the first conductivity type GaAs substrate is within a range from 5,000 to 22,000 pcs/cm².

5. The epitaxial wafer for light emitting diode, according to claim 4, wherein:
the first conductivity type is p-type and the second conductivity type is n-type.

6. The epitaxial wafer for light emitting diode, according to claim 4, wherein:
the first conductivity type is n-type and the second conductivity type is p-type.

7. An epitaxial wafer for light emitting diode, comprising:
a first conductivity type GaAs substrate; and
a layered structure including a first conductivity type AlGaAs cladding layer, a first conductivity type AlGaAs active layer and a second conductivity type AlGaAs window layer sequentially grown on the first conductivity type GaAs substrate by liquid phase epitaxy (LPE) growth using Boat method, and the first conductivity type GaAs substrate being removed by selective etching;
wherein a maximum value of a dislocation density in a plane of the first conductivity type GaAs substrate is within a range from 5,000 to 22,000 pcs/cm².

8. The epitaxial wafer for light emitting diode, according to claim 7, wherein:
the first conductivity type is p-type and the second conductivity type is n-type.

9. The epitaxial wafer for light emitting diode, according to claim 7, wherein:
the first conductivity type is n-type and the second conductivity type is p-type.

10. An epitaxial wafer for light emitting diode, comprising:
a first conductivity type GaAs substrate; and
a layered structure including a first conductivity type AlGaAs active layer and a second conductivity type AlGaAs window layer sequentially grown on the first conductivity type GaAs substrate;
wherein a maximum value of a dislocation density in a plane of the first conductivity type GaAs substrate is within a range from 5,000 to 22,000 pcs/cm².

11. An epitaxial wafer for light emitting diode, comprising:
a first conductivity type GaAs substrate; and
a layered structure including a first conductivity type AlGaAs cladding layer, a first conductivity type AlGaAs active layer and a second conductivity type AlGaAs window layer sequentially grown on the first conductivity type GaAs substrate;
wherein a maximum value of a dislocation density in a plane of the first conductivity type GaAs substrate is within a range from 5,000 to 22,000 pcs/cm².

12. An epitaxial wafer for light emitting diode, comprising:
a first conductivity type GaAs substrate; and
a layered structure including a first conductivity type AlGaAs cladding layer, a first conductivity type AlGaAs active layer and a second conductivity type AlGaAs window layer sequentially grown on the first conductivity type GaAs substrate, and the first conductivity type GaAs substrate being removed by selective etching;
wherein a maximum value of a dislocation density in a plane of the first conductivity type GaAs substrate is within a range from 5,000 to 22,000 pcs/cm².

13. A method of fabricating an epitaxial wafer for light emitting diode, comprising the steps of:
determining a luminance fall rate of the light emitting diode depending on a continuous operation time;
selecting a GaAs substrate having a dislocation density which meets the luminance fall rate determined in the determining step; and
forming a layered structure including an AlGaAs active layer and an AlGaAs window layer sequentially grown on the selected GaAs substrate.

14. The method of fabricating an epitaxial wafer for light emitting diode, according to claim 13, wherein:
the selecting step selects a GaAs substrate having a dislocation density ranging from 5,000 to 22,000 pcs/cm².

15. A method of fabricating an epitaxial wafer for light emitting diode, comprising the steps of:
determining a luminance fall rate of the light emitting diode depending on a continuous operation time;
selecting a GaAs substrate having a dislocation density which meets the luminance fall rate determined in the determining step; and
forming a layered structure including an AlGaAs cladding layer, an AlGaAs active layer and an AlGaAs window layer sequentially grown on the selected GaAs substrate.

16. The method of fabricating an epitaxial wafer for light emitting diode, according to claim 15, wherein:
the selecting step selects a GaAs substrate having a dislocation density ranging from 5,000 to 22,000 pcs/cm².

17. A method of fabricating an epitaxial wafer for light emitting diode, comprising the steps of:
determining a luminance fall rate of the light emitting diode depending on a continuous operation time;
selecting a GaAs substrate having a dislocation density which meets the luminance fall rate determined in the determining step;
forming a layered structure including an AlGaAs cladding layer, an AlGaAs active layer and an AlGaAs window layer sequentially grown on the selected GaAs substrate; and
removing the GaAs substrate by selective etching.

18. The method of fabricating an epitaxial wafer for light emitting diode, according to claim 17, wherein:
the selecting step selects a GaAs substrate having a dislocation density ranging from 5,000 to 22,000 pcs/cm².
